(19) United States
(12) Patent Application Publication
(10) Pub. No.: US 2025/0180995 A1
(43) Pub. Date: Jun. 5, 2025

(54) DEVELOPMENT FOR CHEMICALLY AMPLIFIED RESISTS

(71) Applicant: Applied Materials, Inc., Santa Clara, CA (US)

(72) Inventors: NASRIN KAZEM, Santa Clara, CA (US); LUISA BOZANO, Los Altos Hills, CA (US)

(21) Appl. No.: 18/934,003

(22) Filed: Oct. 31, 2024

Related U.S. Application Data
(60) Provisional application No. 63/605,358, filed on Dec. 1, 2023.

(51) Int. Cl. G03F 7/26; G03F 7/16; G03F 7/20

(52) U.S. Cl. CPC G03F 7/265; G03F 7/16; G03F 7/2026

(57) ABSTRACT

Embodiments described herein relate to a method for developing an exposed resist layer that includes an exposed region and an unexposed region. In an embodiment, the method includes applying a first treatment to the resist layer, where the first treatment is a silylation process. In an embodiment, the method further includes applying a second treatment to the resist layer, where the second treatment is different than the first treatment. In an embodiment, the method further includes developing the resist layer.

### CROSS-REFERENCE TO RELATED APPLICATIONS

This application claims the benefit of U.S. Provisional Application No. 63/605,358, filed on Dec. 1, 2023, the entire contents of which are hereby incorporated by reference herein.

### BACKGROUND

### 1) Field

Embodiments relate to the field of semiconductor manufacturing and, in particular, to development processes for chemically amplified resists (CARs) that include a multi-operation treatment process before development.

### 2) Description of Related Art

Chemically amplified resists (CARs) are based on a polymer photoacid generator (PAG) (or sensitizer) and a base (or quencher). Performance of CAR based resist layers has been limited by a strict correlation between dose, resolution, and roughness (e.g., line edge roughness (LER)). At smaller feature sizes, when approaching dimensions on the scale the molecular structure of the CAR, chemical stochastic speed affects the resist blur. Therefore, LER cannot scale to lower resolutions without sacrificing speed. This is because speed is intrinsically connected to the amount of PAG in the resist. However, speed is an important factor in manufacturing to guarantee competitive ultraviolet (EUV) throughput.

Due to the use of short wavelengths, EUV lithography allows for further scaling to smaller dimensions (e.g., critical dimensions (CDs)). However, EUV lithography suffers greatly from low absorption with existing resist formulations, such as CARs described herein. In order to combat the low absorption, increases in dosage of the EUV radiation is needed. This decreases throughput. Accordingly, the ability to maintain a high speed in other facets of the lithography process is important.

### SUMMARY

Embodiments described herein relate to a method for developing an exposed resist layer that includes an exposed region and an unexposed region. In an embodiment, the method includes applying a first treatment to the resist layer, where the first treatment is a silylation process. In an embodiment, the method further includes applying a second treatment to the resist layer, where the second treatment is different than the first treatment. In an embodiment, the method further includes developing the resist layer.

Embodiments described herein relate to a method of developing a resist layer that has been exposed to form an exposed region and an unexposed region. In an embodiment, the method includes selectively depositing a blocking layer over the unexposed region; and developing the resist layer.

Embodiments described herein relate to a method of developing a resist layer that includes an exposed region and an unexposed region, and where the resist layer includes a chemically amplified resist. In an embodiment, the method includes treating the resist layer with a multi-treatment process that selectively forms a blocking layer over the unexposed region. In an embodiment, the method includes developing the resist layer by removing the exposed region.

### BRIEF DESCRIPTION OF THE DRAWINGS

FIG. 1A is a cross-sectional illustration of a stack with a chemically amplified resist (CAR) layer over a substrate, in accordance with an embodiment.

FIG. 1B is a cross-sectional illustration of the stack after an exposure process, in accordance with an embodiment.

FIG. 1C is a cross-sectional illustration of the exposed stack after a post exposure bake (PEB), in accordance with an embodiment.

FIG. 1D is a cross-sectional illustration of the stack after a first treatment is applied, in accordance with an embodiment.

FIG. 1E is a cross-sectional illustration of the stack after a blocking layer is preferentially applied over the unexposed regions, in accordance with an embodiment.

FIG. 1F is a cross-sectional illustration of the stack after the CAR layer is developed, in accordance with an embodiment.

FIG. 1G is a cross-sectional illustration of the stack after the pattern in the CAR layer is transferred into the underlying substrate, in accordance with an embodiment.

FIG. 2A is a cross-sectional illustration of a CAR layer that is being exposed to a first treatment, in accordance with an embodiment.

FIG. 2B is a cross-sectional illustration of the CAR layer after aluminum is added to form a blocking layer, in accordance with an embodiment.

FIG. 3A is a cross-sectional illustration of a stack with a CAR layer during an exposure process, in accordance with an embodiment.

FIG. 3B is a cross-sectional illustration of the stack after a treatment is applied to the exposed regions of the CAR layer, in accordance with an embodiment.

FIG. 3C is a cross-sectional illustration of the stack after a blocking layer is selectively applied over the unexposed regions, in accordance with an embodiment.

FIG. 3D is a cross-sectional illustration of the stack after the exposed regions are removed with a developing process, in accordance with an embodiment.

FIG. 4A is a cross-sectional illustration of a stack with a CAR layer over a substrate, in accordance with an embodiment.

FIG. 4B is a cross-sectional illustration of the stack after a first treatment is applied to the CAR layer, in accordance with an embodiment.

FIG. 4C is a cross-sectional illustration of the stack after a metal blocking material is added to the unexposed regions, in accordance with an embodiment.

FIG. 5 is a process flow diagram of a process for developing a CAR layer with a multi-operation treatment process, in accordance with an embodiment.

FIG. 6 illustrates a block diagram of an exemplary computer system that may be used in conjunction with a processing tool, in accordance with an embodiment.

### DETAILED DESCRIPTION

Systems described herein include developing processes for chemically amplified resists (CARs). In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, chemically amplified resists (CARs) are an attractive option for advanced lithography processes in order to generate small features (e.g., features with small critical dimensions (CDs)). Advanced lithography processes described herein may refer to extreme ultraviolet (EUV) processes. Though, deep ultraviolet (DUV) and ultraviolet (UV) processes may also benefit from embodiments disclosed herein.

CARs function through the use of conversion of film properties from insoluble to soluble due to chemical deprotection during the amplification process and a post exposure bake (PEB). Wet-development with an aqueous based solution is a common technique to develop the CAR. However, a high contrast between the exposed regions and the unexposed regions is needed to limit areas of partial dissolution in order to improve line edge roughness (LER). Further, capillary forces during wet development techniques and poor surface adhesion can result in pattern collapse or other defects. It has been proposed that dry develop techniques can provide a reduction in pattern collapse and improve LER. However, dry develop chemistries are not fully investigated to date and are not compatible with existing CAR systems.

Accordingly, embodiments disclosed herein may utilize a treatment process that produces a blocking layer that is selectively provided over the unexposed regions. In some embodiments, the blocking layer may comprise a metallic material (e.g., aluminum). This blocking layer can improve contrast between the exposed region and the unexposed region in order to enable dry development processes. Though, embodiments disclosed herein may also be used in conjunction with wet development processes.

In an embodiment, the treatment process is a multi-operation process. Generally, the multi-operation process leverages the photo-induced changes in the exposed versus unexposed regions. A first operation may modify the exposed area to prevent deposition of the blocking layer. For example, a selective silylation process may be used for the first operation. A second operation may selectively deposit the blocking layer over the unexposed regions. For example, the second operation may include one or more of sequential infiltration synthesis (SIS), atomic layer deposition (ALD), or chemical vapor deposition (CVD). The blocking layer may comprise aluminum or another metallic material.

It is to be appreciated that such a surface modification has several benefits. For one, the use of a blocking layer improves the contrast curve. This can provide improved line width roughness (LWR) and LER due to the sharper distinction between partially exposed and exposed regions. Also, the dose to clear is lowered, and a higher sensitivity is provided. Embodiments disclosed herein may also preserve a positive tone development. In contrast, existing surface treatment solutions result in a tone change (i.e., a positive tone resist is converted to a negative tone resist after the treatment). Additionally, the presence of the blocking layer enables dry develop processes which can help reduce LWR and LER, as well as preventing or mitigating pattern collapses.

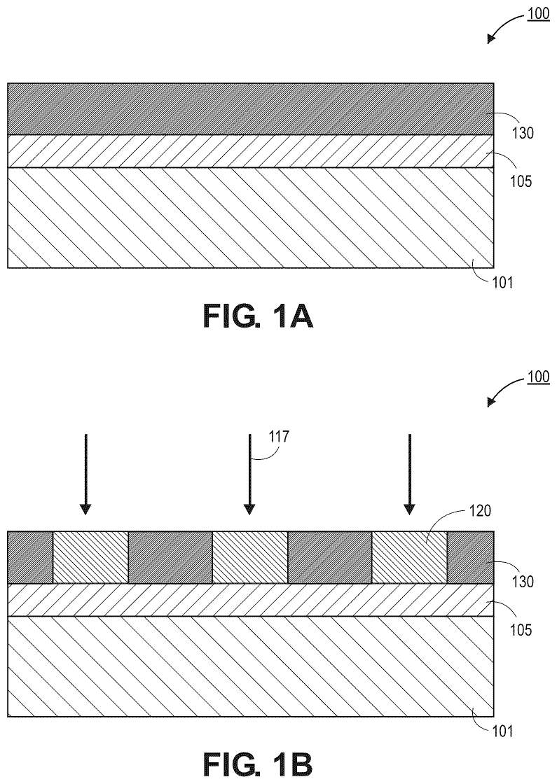

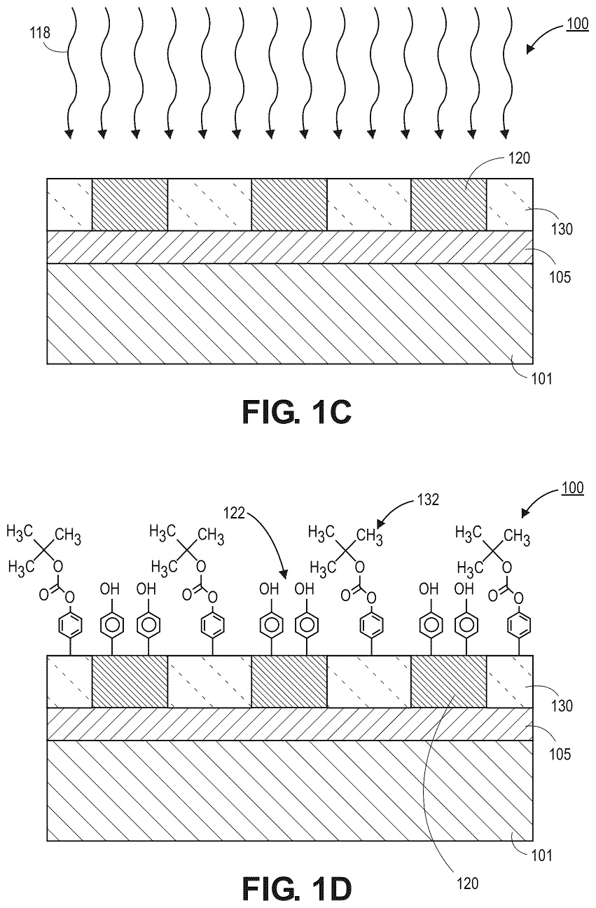

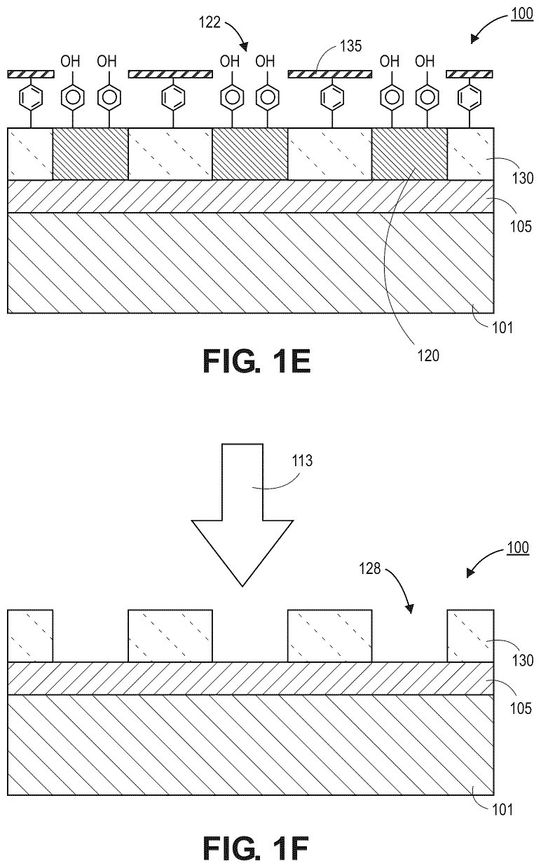

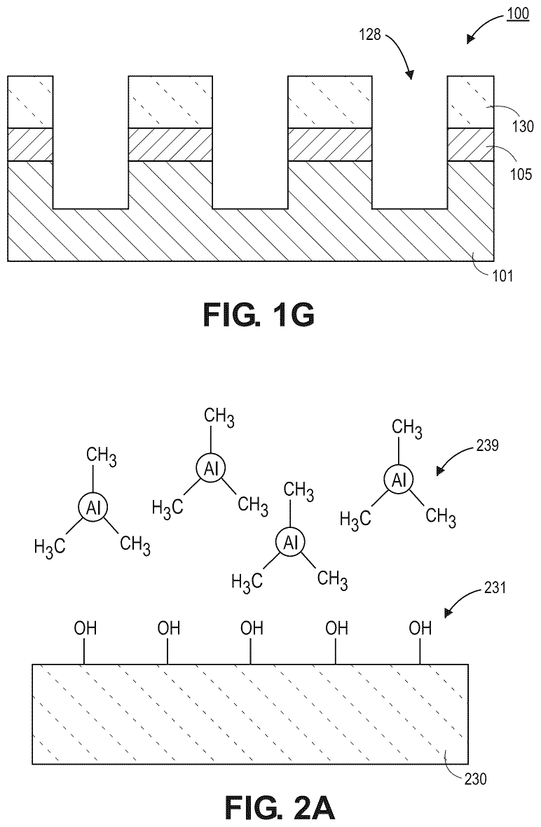

Referring now to FIGS. 1A-1G, a series of cross-sectional illustrations depicting a process for developing a resist layer 130 is shown, in accordance with an embodiment. The resist layer 130 may be exposed, baked, and treated with a multi-operation treatment. The multi-operation treatment may be used to selectively deposit a blocking layer over the unexposed regions. The blocking layer may comprise a metallic element.

Referring now to FIG. 1A, a cross-sectional illustration of a stack 100 is shown, in accordance with an embodiment. The stack 100 may comprise a substrate 101. The substrate 101 may comprise one or more of a semiconductor material (e.g., silicon or the like), a metallic material, a dielectric material, or the like. The substrate 101 may be part of a wafer (e.g., a 300 mm wafer, or the like), or the substrate 101 may have any other form factor. An underlayer 105 may be provided over the substrate 101. The underlayer 105 may comprise one or more of an anti-reflective coating (ARC), a hardmask material, a dielectric, or the like.

In an embodiment, a resist layer 130 is provided over the underlayer 105. The resist layer 130 may be a photoimageable material. Upon exposure to electromagnetic radiation, the resist layer 130 undergoes a chemical change in the exposed regions. The chemical difference between the exposed regions and the unexposed regions generates an etch selectivity that can be used to develop the resist layer 130. In a particular embodiment, the resist layer 130 is tuned to absorb and react to exposure from EUV radiation. Any suitable EUV compatible material composition may be used for the resist layer 130. For example, the resist layer 130 may comprise a CAR material. The CAR material may be based on a polymer (e.g., p-t-butoxycarbonyloxystyrene (PBOCST) or the like) with a photoacid generator (PAG) (or sensitizer) and a base (or quencher).

The resist layer 130 may be applied over the underlayer 105 with any suitable process. In some instances, the resist layer 130 is a flowable material (e.g., a liquid or semi-liquid) that can be deposited with a spin-on process or the like. In other embodiments, the resist layer 130 is applied with a dry deposition process. For example, a chemical vapor deposition (CVD) process, an atomic layer deposition (ALD) process, or a physical vapor deposition (PVD) process may be used to deposit the resist layer 130 over the underlayer 105.

Referring now to FIG. 1B, a cross-sectional illustration of the stack 100 at a subsequent processing operation is shown, in accordance with an embodiment. FIG. 1B illustrates the exposure of the resist layer 130. In an embodiment, electromagnetic radiation 117 (e.g., EUV radiation, DUV radiation, UV radiation, or the like) is used to expose portions of the resist layer 130. The electromagnetic radiation 117 can be selectively directed to exposed regions 120 of the resist layer 130 through any number of radiation focusing or masking processes. For example, a mask or reticle may be used to allow the electromagnetic radiation 117 to pass to only the exposed regions 120. Scanning exposure tools, stepping exposure tools, beams of electromagnetic radiation 117, and/or the like may also be used in order to generate the exposed regions 120.

Referring now to FIG. 1C, a cross-sectional illustration of the stack 100 at a subsequent stage is shown, in accordance with an embodiment. FIG. 1C depicts a post exposure bake (PEB) process. As shown, thermal radiation 118 is directed toward the resist 130. In other embodiments, the substrate 101 may be placed on a hot plate, and thermal energy may be applied to the resist layer 130 up through the stack 100. Any suitable PEB temperatures and/or durations may be used. The PEB may drive diffusion of the photoproducts. Additionally, the PEB may drive the acid-catalyzed reaction that alters the solubility of the polymer in the CAR. Chemical amplification allows individual photoproducts to drive multiple solubility-switching reactions. This may increase sensitivity of the resist layer 130.

Due to the chemical reaction, the exposed regions 120 may be rendered more soluble than the unexposed regions of the resist layer 130. As such, the subsequent develop process (e.g., a wet develop process or a dry develop process) can be used to remove the exposed regions. However, as noted above, the contrast between the exposed regions 120 and the remainder of the resist layer 130 may be sub-optimal. As such, additional treatment processes may be used in order to enhance the contrast.

Referring now to FIG. 1D, a cross-sectional illustration of the stack 100 at a subsequent stage is shown, in accordance with an embodiment. FIG. 1D may show a first operation of a multi-treatment process to the exposed resist layer 130. In an embodiment, the first operation is a treatment that is used to prepare the unexposed regions of the resist layer 130 so that a blocking layer can be selectively deposited in a subsequent operation.

The selective treatment is enabled by taking advantage of the surface modification in the exposed region 120 where the PAG causes a release of H+ species. In one embodiment, the first operation may comprise a silylation process. For example, hexamethyldisilazane (HMDS) may be applied to the stack 100. This results in a first chemical structure 132 being provided over the unexposed regions of the resist layer 130 and a second chemical structure 122 being provided over the exposed regions 120. Depending on the source gas used for the silylation, the first chemical structure 132 can have any suitable composition. For example, in the case of HMDS, the first chemical structure 132 may comprise oxygen, carbon, and hydrogen that is bonded to a benzene ring. The second chemical structure 122 may comprise oxygen and hydrogen bonded to a benzene ring.

Referring now to FIG. 1E, a cross-sectional illustration of the stack 100 at a subsequent stage is shown, in accordance with an embodiment. In FIG. 1E, a second operation is implemented in order to form a blocking layer 135 over the unexposed regions of the resist layer 130. In an embodiment, the second operation may include an SIS treatment that produces the blocking layer 135. Due to the reactivity of the first chemical structure 132, the blocking layer 135 preferentially deposits over the unexposed region of the resist layer 130. The SIS treatment may include introducing a metal containing precursor to form a metal containing material (e.g., aluminum, alumina) on the resist layer 130. Though, non-metal SIS processes may also be used in some embodiments.

In the illustrated embodiment, the blocking layer 135 is shown schematically as rectangular boxes that are chemically coupled to the unexposed regions of the resist layer 130. However, it is to be appreciated that the blocking layer 135 may be directly coupled to the unexposed regions of the resist layer 130, or the metallic elements (e.g., aluminum) may be chemically bonded to portions of the first chemical structure 132.

In the embodiment described in FIG. 1E, the second operation is described as an SIS treatment. However, it is to be appreciated that other selective deposition processes may also be used in some embodiments. For example, the second operation may include an ALD process or a CVD process. In such alternative deposition processes, a metallic precursor gas may preferentially deposit onto the first chemical structure 132.

Referring now to FIG. 1F, a cross-sectional illustration of the stack 100 at a subsequent stage is shown, in accordance with an embodiment. In FIG. 1F, a development process 113 is implemented in order to remove the exposed regions 130 to provide a pattern 128 in the resist layer 130. In the embodiment shown in FIG. 1F, the blocking layer 135 and any chemical links to the blocking layer 135 from the resist layer 130 are omitted for simplicity. Though, in practice the blocking layer 135 will substantially persist through the development process 113.

The development process 113 may comprise a wet develop process or a dry develop process. In the case of a wet develop process, the extra contrast provided by the blocking layer 135 allows for a decrease in the dose to clear and a higher sensitivity is provided. LER and LWR may also be improved. The blocking layer 135 also enables the use of dry develop processes that were previously unobtainable with existing chemistries. As noted above dry develop processes allow for improved LER and LWR, as well as mitigation or elimination of pattern collapse.

Referring now to FIG. 1G, a cross-sectional illustration of the stack 100 at a subsequent processing operation is shown, in accordance with an embodiment. FIG. 1G illustrates the transfer of the pattern 128 into the substrate 101. In the embodiment shown in FIG. 1G, the blocking layer 135 and any chemical links to the blocking layer 135 from the resist layer 130 are omitted for simplicity. Though, in practice the blocking layer 135 will substantially persist through the process shown in FIG. 1G. In an embodiment, the pattern 128 may be transferred into the substrate 101 by an etching process. A first etching process may remove portions of the underlayer 105, and a second etching process may remove portions of the substrate 101. The etching processes may use a dry etching chemistry (e.g., plasma based processes) or wet etching chemistry.

In the case of a dry etching chemistry, embodiments may include using a single chamber (not shown) for the resist developing and the substrate etching. For example, a first plasma chemistry may be used for developing the resist layer 130, and a second plasma chemistry may be used to etch the underlayer 105 and/or the substrate 101. This allows for fewer transfers of the substrate 101 between tools and can increase throughput. Minimizing transfer of the substrate 101 can also reduce defect generation (e.g., by preventing particles or the like from depositing on the stack 100).

Referring now to FIGS. 2A and 2B, a series of cross-sectional illustrations depicting a process for depositing a blocking layer 235 on a resist layer 230 is shown, in accordance with an embodiment. In the embodiment shown in FIGS. 2A and 2B, the blocking layer 235 is deposited with an ALD or a CVD process.

Referring now to FIG. 2A, a cross-sectional illustration of a resist layer 230 is shown, in accordance with an embodiment. The resist layer 230 may be a CAR layer in some embodiments. The CAR material may be similar to any of the CAR material compositions described in greater detail herein. The resist layer 230 may be adjacent to unexposed regions (not shown in FIG. 2A). That is, portions of the resist layer 230 may have been exposed. In some embodiments, the resist layer 230 has also been baked with a PEB process. The baking process may result in the formation of a first chemical structure 231 that extends up from the resist layer 230. In an embodiment, the first chemical structure 231 may include dangling bonds with elements comprising oxygen or hydrogen.

In an embodiment, a processing gas 239 may be flown into the chamber (not shown) in order to initiate the deposition of the blocking layer 235. In an embodiment, the processing gas 239 may be a metallic precursor. Any suitable metallic element may be used. For example, the metallic element may comprise aluminum. The aluminum may be chemically bonded to non-metallic elements, such as carbon, oxygen, hydrogen, or the like. For example, carbon is coupled to the aluminum center in FIG. 2A. The processing gas 239 may be flown into the chamber with an ALD type process or a CVD type process.

Referring now to FIG. 2B, a cross-sectional illustration of the resist layer 230 after the blocking layer 235 is formed over the resist layer 230 is shown, in accordance with an embodiment. As shown, the processing gas 239 may react with the first chemical structure 231 to form the blocking layer 235. The blocking layer 235 may comprise a metallic element that is chemically bonded to the resist layer 230. For example, an oxygen element may be provided between the resist layer 230 and the metallic element (e.g., aluminum).

After the blocking layer 235 is formed, the resist layer 230 may continue with a developing process and a pattern transfer process. The developing process may include the removal of exposed regions (not shown). The developing process may be a dry develop process or a wet develop process, similar to embodiments described in greater detail above. The subsequent etching process into an underlying substrate (not shown) may be a wet or dry etching process, similar to embodiments described in greater detail above.

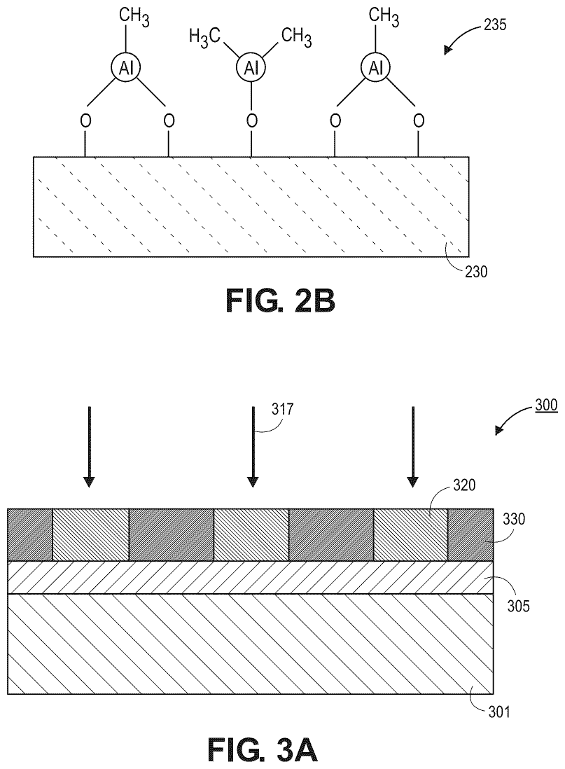

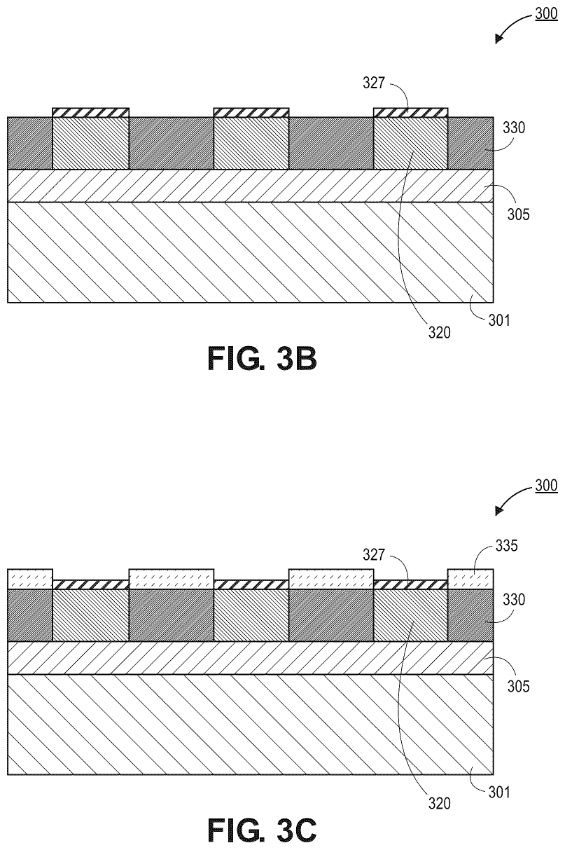

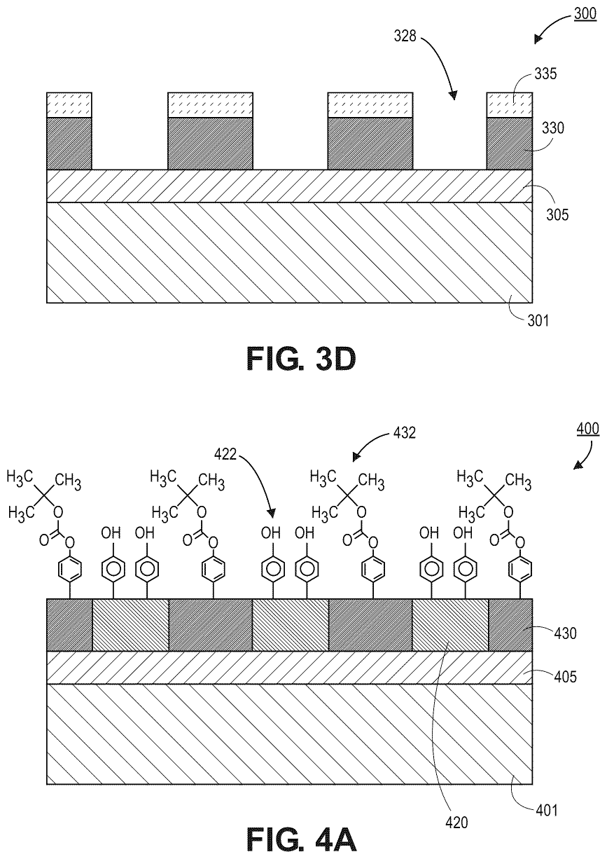

Referring now to FIGS. 3A-3D, a series of cross-sectional illustrations depicting a process for treating an exposed resist is shown, in accordance with an embodiment. In an embodiment, a multi-treatment process is used in order to enhance contrast. The first treatment provides a barrier on the exposed regions, and the second treatment preferentially deposits the blocking layer on the unexposed regions. That is, the barrier layer prevents the blocking layer from be disposed on the exposed regions.

Referring now to FIG. 3A, a cross-sectional illustration of a stack 300 is shown, in accordance with an embodiment. The stack 300 may comprise a substrate 301 with an underlayer 305 over the substrate 301. The substrate 301 and the underlayer 305 may be similar to any substrate or underlayer described in greater detail herein. In an embodiment, a resist layer 330 may be provided over the underlayer 305. The resist layer 330 may be a CAR layer similar to any of the CAR materials described in greater detail herein. In an embodiment, the resist layer 330 has undergone an exposure 317 to provide exposed regions 320 within the resist layer 330. The exposure 317 may be similar to any of the exposure processes described in greater detail herein.

Referring now to FIG. 3B, a cross-sectional illustration of the stack 300 at a subsequent stage is shown, in accordance with an embodiment. Particularly, a barrier 327 is provided on the exposed regions 320. The barrier 327 may be preferentially applied to the exposed regions 320 through the use of chemical differences in the exposed regions 320 and the unexposed regions of the resist layer 330. The chemical differences may be generated, at least in part, by the exposure 317 and a PEB process (not shown). A more detailed explanation of the chemistry will be provided in greater detail below.

Referring now to FIG. 3C, a cross-sectional illustration of the stack 300 at a subsequent stage is shown, in accordance with an embodiment. As shown, a blocking layer 335 is selectively deposited over the unexposed regions of the resist layer 330. In a particular embodiment, the blocking layer 335 is applied with an ALD process or a CVD process. The barrier 327 may prevent the deposition of the blocking layer 335 over the exposed regions 320. In an embodiment, the blocking layer 335 may comprise a metallic element. For example, the blocking layer 335 may comprise aluminum in some embodiments.

Referring now to FIG. 3D, a cross-sectional illustration of the stack 300 after a developing process is shown, in accordance with an embodiment. The developing process may be similar to any of the developing processes described in greater detail herein. For example, the developing process may include a wet develop or a dry develop. The developing process selectively removes the exposed regions 320. As such, a positive tone resist is maintained, while obtaining the benefits of improved contrast, sensitivity, LER, LWR, and/or the like.

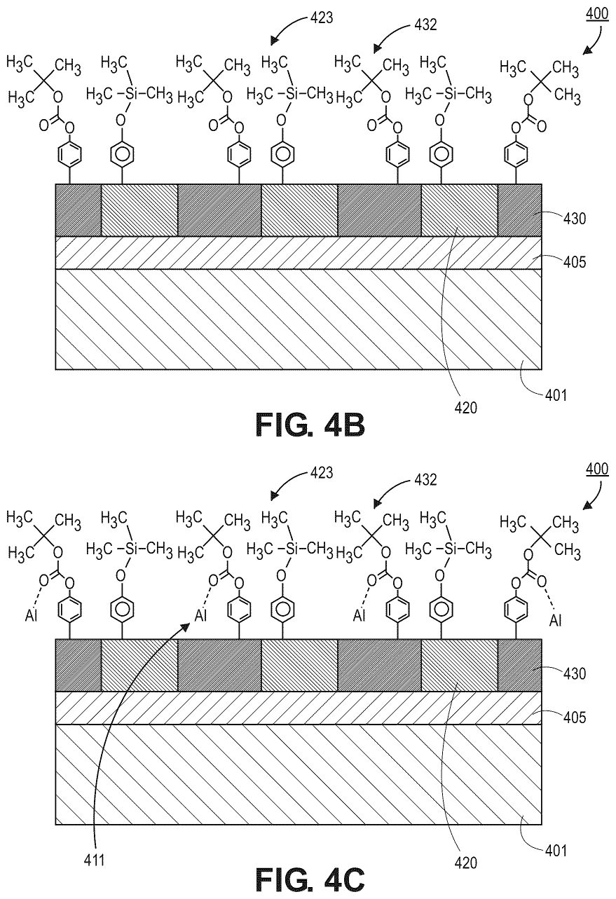

Referring now to FIGS. 4A-4C, a series of cross-sectional illustrations depicting a process for forming a positive tone resist with a multi-process surface treatment is shown, in accordance with an embodiment. The first treatment is a barrier treatment that is applied to the exposed regions of the resist layer, and the second treatment is a deposition process that integrates a metallic component into the unexposed regions of the resist layer. The second treatment may include an ALD process or a CVD process.

Referring now to FIG. 4A, a stack 400 that comprises a substrate 401 with an underlayer 405 over the substrate 401 is shown, in accordance with an embodiment. The substrate 401 and the underlayer 405 may be similar to any substrate or underlayer described in greater detail herein. In an embodiment, a resist layer 430 may be provided over the underlayer 405. The resist layer 430 may be a CAR layer similar to any of the CAR materials described in greater detail herein. In an embodiment, the resist layer 430 has undergone an exposure to provide exposed regions 420 within the resist layer 430. The exposure may be similar to any of the exposure processes described in greater detail herein.

As shown, the exposed regions 420 may have first chemical structures 422, and the unexposed regions of the resist layer 430 may have second chemical structures 432. The first chemical structures 422 and the second chemical structures 432 may be different than each other. For example, the first chemical structures 422 may be more reactive to a silylation process. In one embodiment, the first chemical structures 422 comprise a benzene ring bonded to an oxygen and hydrogen pair.

Referring now to FIG. 4B, a cross-sectional illustration of the stack 400 after a first treatment is implemented to form a barrier layer on the exposed regions 420 is shown, in accordance with an embodiment. As shown, the barrier layer is embodied by a third chemical structure 423. The third chemical structure 423 may be formed through a silylation process. For example, exposure to HMDS may be used in order to form the third chemical structure 423. The third chemical structure 423 is resistant to a subsequent deposition process that aims to integrate a metallic element into the stack 400 in order to form a blocking layer.

Referring now to FIG. 4C, a cross-sectional illustration of the stack 400 after a second treatment is implemented to form a blocking layer on the unexposed regions of the resist layer 430 is shown, in accordance with an embodiment. As shown, a metallic element 441 is integrated into the second chemical structure 432. For example, the metallic element 441 may comprise aluminum. The metallic element 441 may be introduced to the stack 400 through an ALD process or a CVD process that uses a metallic precursor gas. For example, the metallic precursor gas may comprise trimethylaluminum (TMA). In an embodiment, the metallic element 441 mechanically strengthens and provides improved resistance to developer etching chemistries. As such, the exposed regions 420 (and the third chemical structures 423) can be easily removed with either a wet or dry developing process.

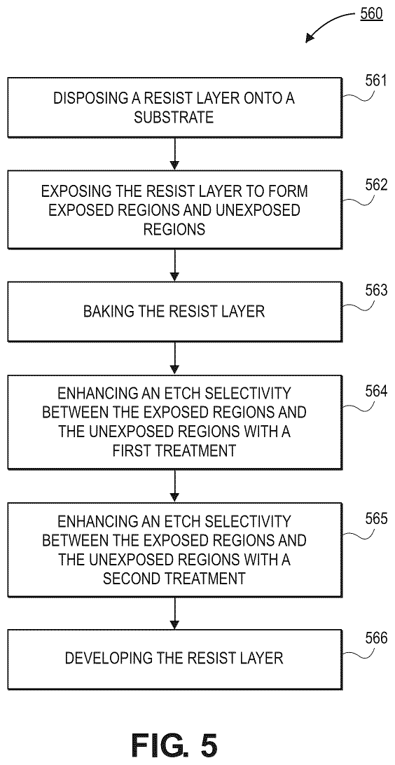

Referring now to FIG. 5, a process flow diagram of a process 560 for developing a resist layer is shown, in accordance with an embodiment. The process 560 may include a double treatment operation that enhances the contrast between exposed regions and unexposed regions of the resist layer. In some embodiments, the double treatment may allow for either a wet develop process or a dry develop process.

In an embodiment, process 560 may begin with operation 561, which comprises disposing a resist layer onto a substrate. The resist layer may be a CAR that is similar to any of the CAR compositions described in greater detail herein. The resist layer may be disposed onto the substrate with a spin coating process, a lamination process, a deposition process (e.g., CVD, ALD, etc.), or any other suitable process. In an embodiment, a preliminary bake may be implemented on the resist layer after deposition and before exposure.

In an embodiment, process 560 may continue with operation 562, which comprises exposing the resist layer to form exposed regions and unexposed regions. The exposure process may include EUV, DUV, or UV electromagnetic radiation that is focused and/or selectively directed onto the resist layer. The exposure process may be similar to any of the exposure processes described in greater detail herein.

In an embodiment, the process 560 may continue with operation 563, which comprises baking the resist layer. The baking operation may be any typical PEB process that is used to drive diffusion and repeated reaction of the photoproducts to drive the solubility switch in the resist layer. The baking parameters (e.g., time, temperature, etc.) may be any suitable values for processing a given resist layer.

In an embodiment, the process 560 may continue with operation 564, which comprises enhancing an etch selectivity between the exposed regions and the unexposed regions with a first treatment. The first treatment may include a process that prepares the unexposed regions for a subsequent metal deposition. In one embodiment, the first treatment modifies dangling bonds of the unexposed region to prepare them for subsequent reaction with a metal containing precursor. In other embodiments, the first treatment forms a barrier layer on the exposed regions that prevents subsequent integration with a metal containing precursor. In a particular embodiment, the first treatment may comprise a silylation process that uses HMDS or the like.

In an embodiment, process 560 may continue with operation 565, which comprises enhancing an etch selectivity between the exposed regions and the unexposed regions with a second treatment. The second treatment may comprise a surface modification that integrates a metallic element into the unexposed regions. The metallic element may be any suitable metal element, such as aluminum or the like. In an embodiment, the second treatment may include an SIS treatment, an ALD process, or a CVD process. The metallic element may be chemically bonded to dangling bonds on the unexposed regions, or the metallic element may be formed as a discrete metal containing layer over the unexposed regions. The metallic element may be sourced from a metallic precursor such as, but not limited to, TMA or the like.

In an embodiment, the process 560 may continue with operation 566, which comprises developing the resist layer. The developing process may include a wet developing process or a dry developing process. With respect to a dry develop process, the blocking layer (e.g., the metal containing component) generated through the double treatment process allows for the dry develop chemistry to be used in conjunction with the CAR material composition. As such, improved LER/LWR can be obtained while preventing or mitigating pattern collapse. As such, CAR material systems can be scaled to smaller CDs while maintaining suitable throughput and optimal pattern transfer into an underlying substrate. After the resist layer is developed, etching processes (e.g., dry or wet etching) may be used to transfer the pattern in the resist layer into the underlying substrate.

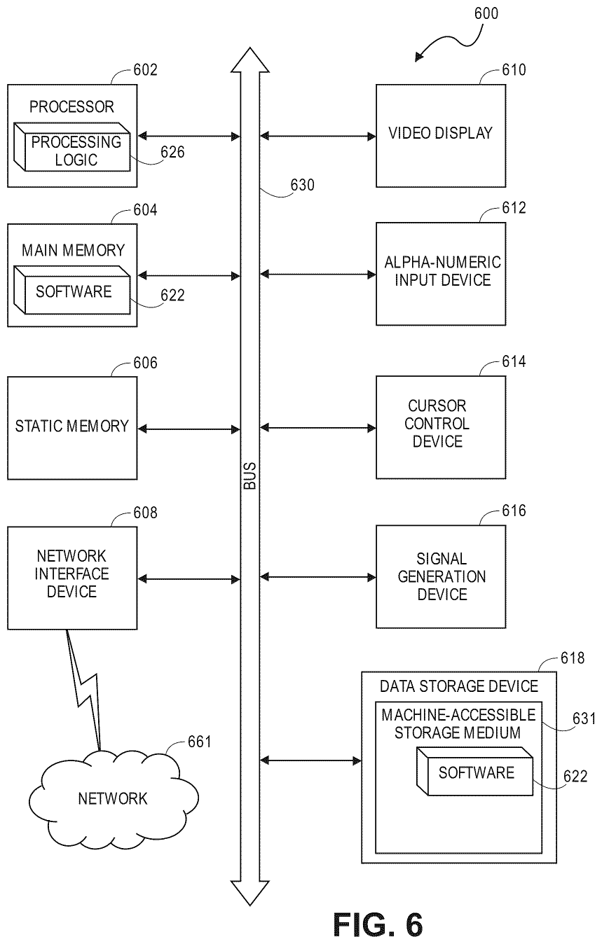

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 632 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 620 via the system network interface device 608. In an embodiment, the network interface device 608 may operate using RF coupling, optical coupling, acoustic coupling, or inductive coupling.

While the machine-accessible storage medium 632 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method for developing an exposed resist layer that comprises an exposed region and an unexposed region, the method comprising:
applying a first treatment to the resist layer, wherein the first treatment is a silylation process;
applying a second treatment to the resist layer, wherein the second treatment is different than the first treatment; and
developing the resist layer.

2. The method of claim 1, wherein the silylation process comprises hexamethyldisilazane (HMDS).

3. The method of claim 1, wherein the second treatment comprises sequential infiltration synthesis (SIS).

4. The method of claim 1, wherein the second treatment comprises atomic layer deposition (ALD) or chemical vapor deposition (CVD).

5. The method of claim 1, wherein the second treatment forms a metallic material on the unexposed region.

6. The method of claim 5, wherein the metallic material comprises aluminum.

7. The method of claim 1, wherein developing the resist layer is a dry process.

8. The method of claim 1, wherein developing the resist layer is a wet process.

9. The method of claim 1, wherein the resist layer comprises a chemically amplified resist (CAR).

10. A method of developing a resist layer that has been exposed to form an exposed region and an unexposed region, the method comprising:
selectively depositing a blocking layer over the unexposed region; and
developing the resist layer.

11. The method of claim 10, wherein the blocking layer is selectively deposited over the unexposed region by applying a first treatment and a second treatment to the resist layer.

12. The method of claim 11, wherein the first treatment comprises a silylation process, and wherein the second treatment comprises at least one of sequential infiltration synthesis (SIS), atomic layer deposition (ALD), or chemical vapor deposition (CVD).

13. The method of claim 11, wherein the blocking layer comprises aluminum.

14. The method of claim 10, wherein the resist layer is a chemically amplified resist (CAR).

15. The method of claim 10, further comprising:
baking the resist layer before exposing the resist layer.

16. The method of claim 10, wherein developing the resist layer comprises removing the exposed region.

17. A method of developing a resist layer that comprises an exposed region and an unexposed region, and wherein the resist layer comprises a chemically amplified resist, the method comprising:
treating the resist layer with a multi-treatment process that selectively forms a blocking layer over the unexposed region; and
developing the resist layer by removing the exposed region.

18. The method of claim 17, wherein the multi-treatment process comprises a silylation process and one of a sequential infiltration synthesis (SIS), atomic layer deposition (ALD), or chemical vapor deposition (CVD).

19. The method of claim 17, wherein developing the resist layer is a dry develop process or a wet develop process.

20. The method of claim 17, wherein the blocking layer comprises aluminum.
